(19) United States
(12) Patent Application Publication
(10) Pub. No.: US 2020/0058890 A1
(43) Pub. Date: Feb. 20, 2020

(54) LIGHT EMITTING DEVICE AND MANUFACTURING METHOD THEREOF

(71) Applicant: INT TECH CO., LTD., Hsinchu County (TW)

(72) Inventors: FENG YU HUANG, MIAOLI COUNTY (TW); HUEI-SIOU CHEN, TAIPEI CITY (TW); CHENG-HSIN CHEN, HSINCHU COUNTY (TW)

(21) Appl. No.: 16/232,679

(22) Filed: Dec. 26, 2018

Related U.S. Application Data
(60) Provisional application No. 62/719,039, filed on Aug. 16, 2018.

(51) Int. Cl. H01L 51/50; H01L 51/52; H01L 51/56; H01L 27/32

(52) U.S. Cl. CPC H01L 51/5012; H01L 51/5056; H01L 51/5072; H01L 2227/323; H01L 51/5253; H01L 51/56; H01L 27/3246; H01L 51/5092

(57) ABSTRACT

The present disclosure provides a light emitting device. The light emitting device includes a substrate, and an array of light emitting units over the substrate. Each of the light emitting units includes a first electrode. The first electrode includes a bottom surface on the substrate, a top surface opposite to the bottom surface, and a sidewall between the bottom surface and the top surface. Each of the light emitting units further includes a second electrode over the first electrode and facing the top surface. Each of the light emitting units further includes an organic layer between the first electrode and the second electrode. The organic layer at least partially covers the top surface and a meeting point of the top surface and the sidewall. The organic layer is discontinuous among the light emitting units. A method for manufacturing a light emitting device is also provided.

### PRIORITY CLAIM AND CROSS-REFERENCE

This application claims the benefit of prior-filed provisional application No. 62/719,039, filed Aug. 16, 2018.

### TECHNICAL FIELD

The present disclosure is related to light emitting device, especially to an organic light emitting device and manufacturing method thereof.

### BACKGROUND

Organic light emitting display (OLED) has been used widely in most high end electron devices. However, due to the constraint of current technology, the pixel definition is realized by coating a light emitting material on a substrate through a mask, and often, the critical dimension on the mask can not be smaller than 100 microns. Therefore, pixel density having 800 ppi or higher becomes a difficult task for an OLED maker.

### SUMMARY

In the present disclosure, the light emitting units are formed by a photo sensitive material. The photo sensitive material is directly disposed on a substrate without a pixel defined layer. The pixel definition is realized by a photolithography process.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a light emitting device, in accordance with some embodiments of the present disclosure.

FIG. 2 is top view of a portion of a light emitting device, in accordance with some embodiments of the present disclosure.

FIGS. 3 to 16 illustrate a method of manufacturing a light emitting device, in accordance with some embodiments of the present disclosure.

FIGS. 17A to 17C illustrate cross sectional views along ling AA in FIG. 2, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a light emitting device, especially, organic light emitting device (OLED), and a method of manufacturing thereof. In the present disclosure, an organic light emitting layer in the OLED is formed by photo lithography. In some embodiments, the organic light emitting layer is a polymer light emitting layer. In some embodiments, the organic light emitting layer includes several light emitting pixels or units.

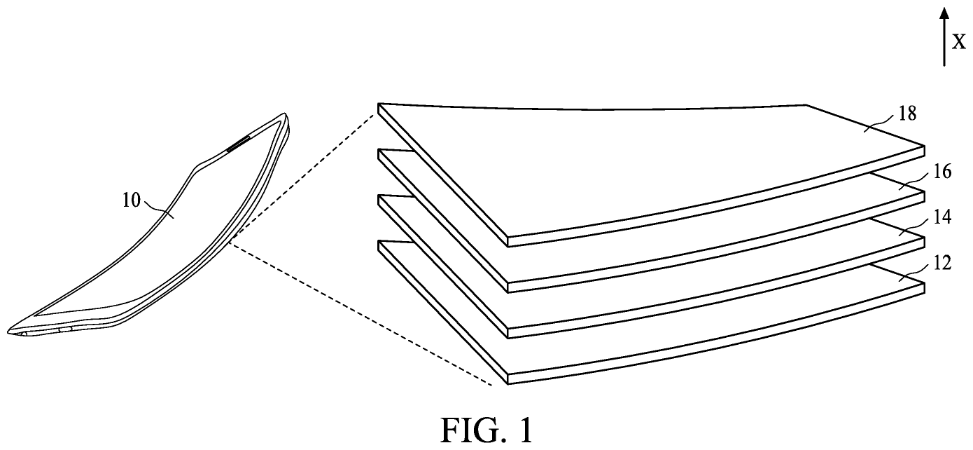

Referring to FIG. 1, FIG. 1 is a light emitting device 10, in accordance with some embodiments of the present disclosure. The light emitting device 10 can he a rigid or a flexible display. In some embodiments, the light emitting device 10 may have at least four different layers substantially stacked along a thickness direction X. In some embodiments, the at least four different layers includes layers 12 to 18, as shown in FIG. 1. In some embodiments, layer 12 is a substrate configured as a platform to have a light emitting layer 14 disposed thereon. Layer 16 is a cap layer to be disposed on the light emitting layer 14 and layer 18 is configured as a window for light emitting in/out the electronic device 10. In some embodiments, layer 16 is an encapsulation layer. In some embodiments, layer 18 can also be configured as a touch interface for the user, therefore the surface hardness of the might be high enough to meet the design requirement. In some embodiments, layer 16 and layer 18 are integrated into one layer.

In some embodiments, layer 12 might be formed with a polymer matrix material. In some embodiments, layer 12 has a bend radius being not greater than about 3 mm. In some embodiments, layer 12 has a minimum bend radius being not greater than 10 mm. The minimum bend radius is measured to the inside curvature, is the minimum radius one can bend layer 12 without kinking it, damaging it, or shortening its life. In some embodiments, several conductive traces may be disposed in layer 12 and form circuitry to provide current to the light emitting layer 14. In some embodiments, layer 12 includes graphene.

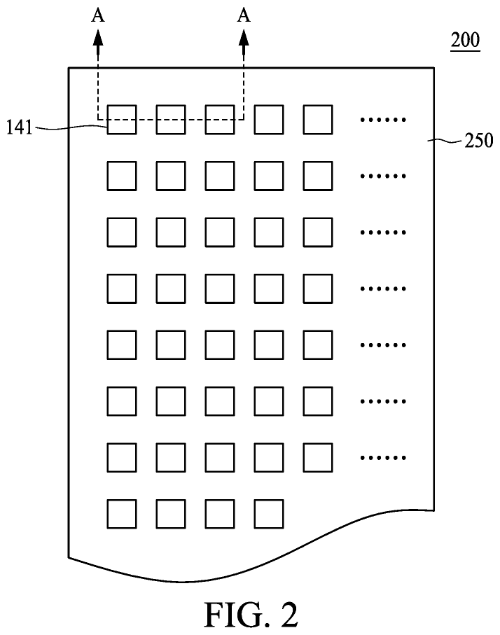

Referring to FIG. 2, FIG. 2 is top view of a portion of a light emitting device, in accordance with some embodiments of the present disclosure.

In some embodiments, a light emitting layer 200 may include many light emitting units 141. In some embodiments, the light emitting units may also be referred as light emitting pixels. In some embodiments, the light emitting layer 200 has a substrate 250. In some embodiments, the substrate 250 is configured to be able to provide current to the light emitting units 141. In some embodiments, the light emitting units 141 are configured as mesa disposed on the substrate 250. In some embodiments, the light emitting units 141 are configured to be in recesses of the substrate 250. In some embodiments, the light emitting units 141 can be arranged in an array. Each independent light emitting unit is separated from other adjacent light emitting units. In some embodiments, the separation distance between two adjacent light emitting units is between about 2 nm and about 100 um. In some embodiments, the separation distance is controlled to be at least not greater than about 50 um so that the density of the light emitting units 141 can be designed to be at least more than 700 ppi or 1200 ppi.

In some embodiments, a light emitting unit 141 has a width being between about 2 nm and about 500 um. In some embodiments the width is not greater than about 2 um.

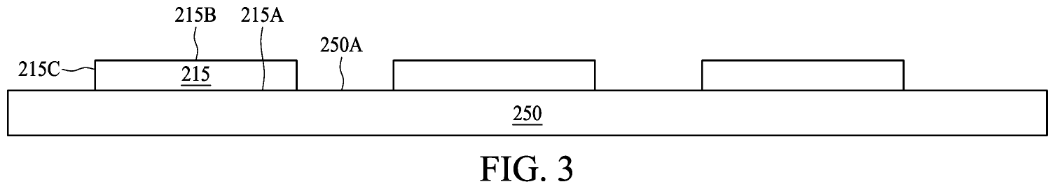

Referring to FIGS. 3 to 16, FIGS. 3 to 16 illustrate a method of manufacturing a light emitting device, in accordance with some embodiments of the present disclosure. Cross sectional views along ling AA in FIG. 2 are illustrated in FIGS. 3 to 16.

In FIG. 3, a substrate 250 is provided. The substrate 250 may include a TFT (thin film transistor) array. Several first electrodes 215 are disposed over a top surface 250A of the substrate 250. In some embodiments, each first electrode 215 includes a bottom surface 215A, a top surface 215B opposite to the bottom surface, and a sidewall 215C between the bottom surface 215A and the top surface 215B. In some embodiments, each first electrode 215 is configured to be connected to a circuit embedded in the substrate 250 at one side and to be in contact with a light emitting material at the other side. In some embodiments, the pattern of the first electrode array is designed for the pixel arrangement. In some embodiments, the top surface 250A of the substrate 250 is partially exposed through the first electrodes 215.

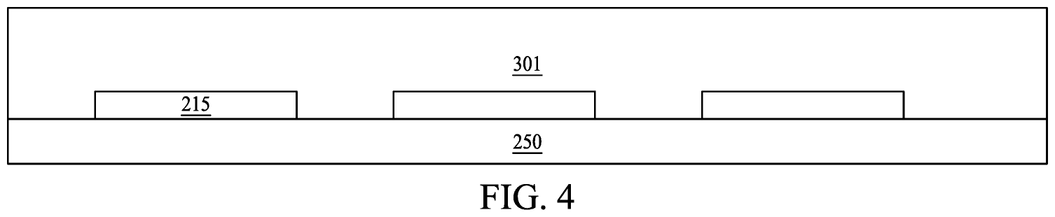

In FIG. 4, a buffer layer 301 is disposed over and covers the first electrodes 215. In some embodiments, the buffer layer 301 covers the top surface 215B and the sidewall 215C of the first electrodes 215. In some embodiments, the buffer layer 301 covers the exposed top surface 250A of the substrate 250. In some embodiments, the buffer layer 301 fills into the gaps between adjacent first electrodes 215. In some embodiments, the buffer layer 301 may be used to block moisture penetrating into the first electrodes 215 and the substrate 250.

In some embodiments, the buffer layer 301 is disposed by spin coating, or jetting. In some embodiments, the buffer layer 301 can be further heated. In some embodiments, the heating operation is about 1 to 10 minutes. In some embodiments, the buffer layer 301 includes fluorine.

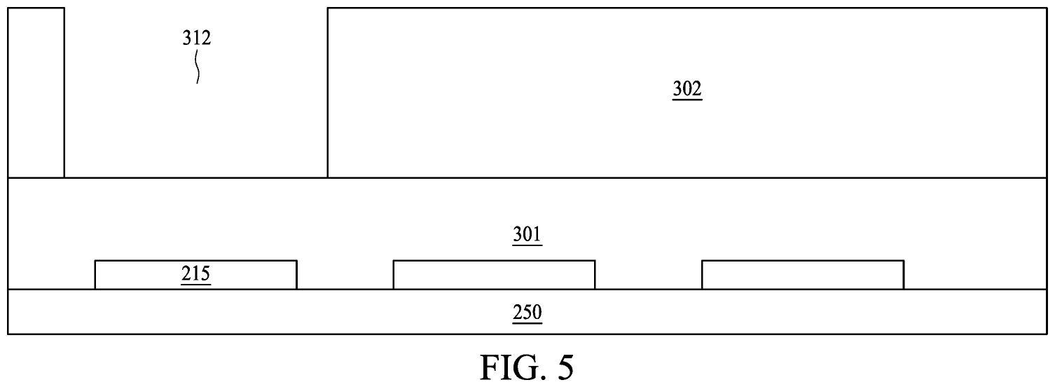

In FIG. 5, a photosensitive layer 302 is disposed over the buffer layer 301. In some embodiments, the photosensitive layer 302 is disposed over the buffer layer 301 after the heating operation.

In some embodiments, the photosensitive layer 302 is disposed by spin coating, or jetting. In some embodiments, the photosensitive layer 302 is spin-coated over the buffer layer 301. In some embodiments, the photosensitive layer 302 is further patterned by a lithography process to expose a portion of buffer layer 301 through a recess 312.

In some embodiments, the photosensitive layer 302 may include positive photoresist or negative photoresist. In some embodiments, the photosensitive layer 302 may include organic materials and inorganic materials. In some embodiments, organic materials may include, for examples, phenol-formaldehyde resins, epoxy resins, Ethers, Amities, Rubbers, acrylic acids, acrylic resins, acrylic epoxy resins, acrylic melamine. In some embodiments, inorganic materials may include, for examples, metal oxides and silicide. In some embodiments, the photosensitive layer 302 may include one layer of a material. In some embodiments, the photosensitive layer 302 may include several layers of different materials, such as one organic material layer stacking on one inorganic material layer.

In some embodiments, with respect to the top surface 250A of the substrate 250, the photosensitive layer 302 has a larger adhesive force than the buffer layer 301. In some embodiments, with respect to the top surface 215B and the sidewall 215C of the first electrodes 215, the photosensitive layer 302 has a larger adhesive force than the buffer layer 301. In some embodiments, the buffer layer 301 may be used to provide a less adhesive force between the substrate 250 and the photosensitive layer 302.

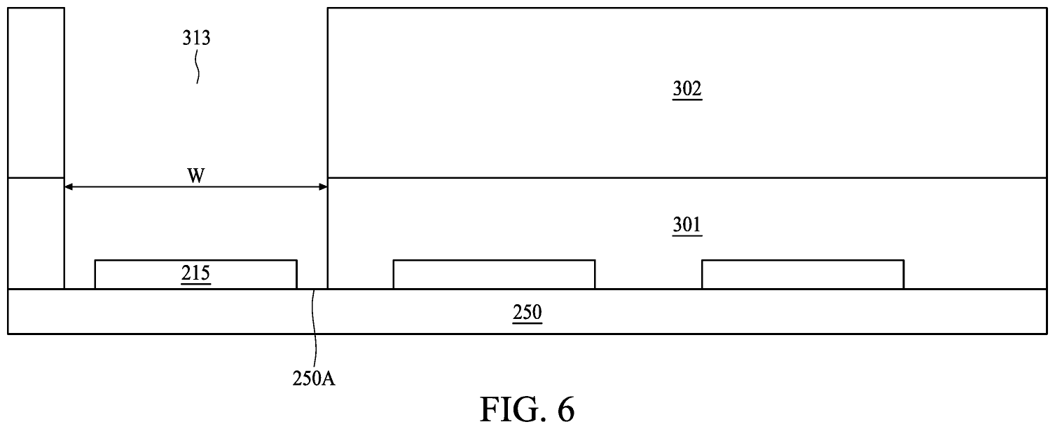

In FIG. 6, a portion of the buffer layer 301 is removed to have a recess 313 to expose one of the first electrodes 215. In some embodiments, the top surface 250A of the substrate 250 is partially exposed through the buffer layer 301 and the photosensitive layer 302. In some embodiments, the removal operation in FIG. 6 is performed by wet etch.

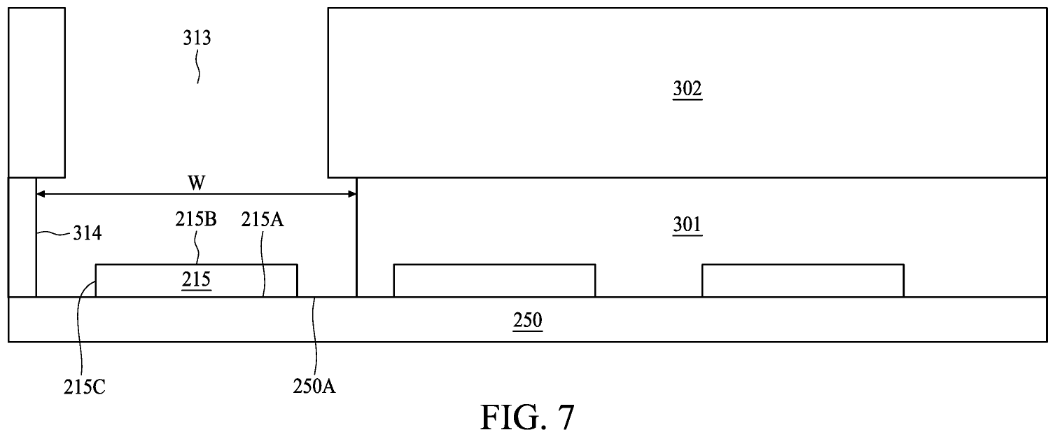

For some embodiments, the removal operation includes at least two steps. The first step is vertical removal and the buffer layer 301 is carved out substantially following the dimension of opening width of the recess 312 as shown in FIG. 6. After forming the recess 313, a second step is introduced to perform a lateral removal as shown in FIG. 7. An undercut 314 is formed to expand the recess 313 further into the buffer layer 301 in order to expose more top surface 250A of the substrate 250.

For some embodiments, the removal operation includes only the vertical removal, and the buffer layer 301 is carved out substantially following the dimension of opening width of the recess 312.

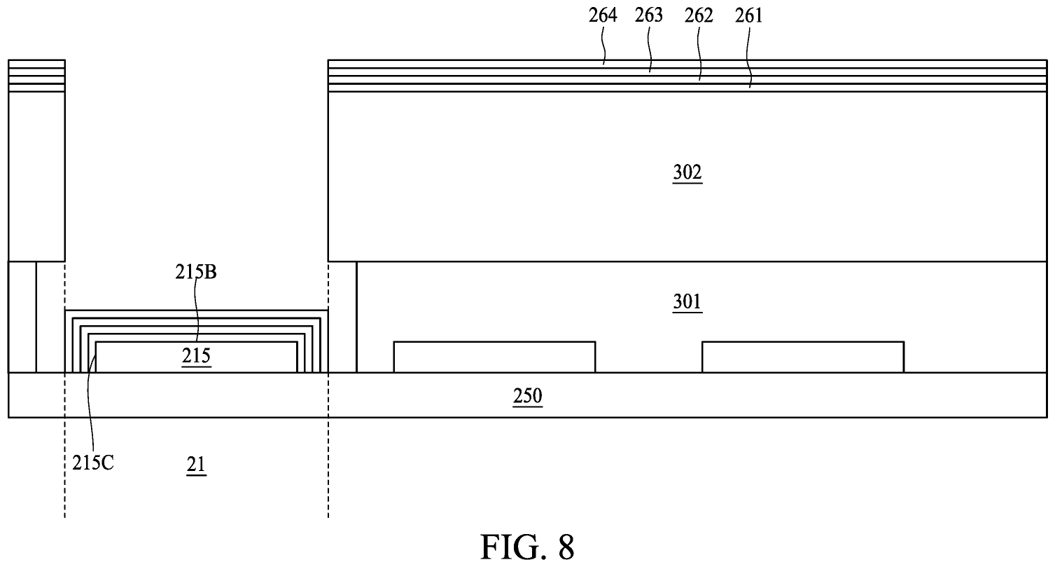

In FIG. 8, a first type carrier injection layer 261, a first type carrier transportation layer 262, an organic emissive layer (EM) layer 263, and a second type carrier transportation layer 264 are sequentially disposed over the exposed first electrode 215 of a light emitting unit 21 and the exposed top surface 250A. The buffer layer 301 and the photosensitive layer 302 cover the other first electrodes 215 except the first electrode 215 of the light emitting unit 21.

In some embodiments, the first type carrier injection layer 261 is an electron injection layer (EEL) and the first type carrier transportation layer 262 is an electron transportation layer (ETL). In some embodiments, the first type carrier injection layer 261 is a hole injection layer (HIL) and the first type carrier transportation layer 262 is a hole transportation layer (HTL). In some embodiments, the second type carrier transportation layer 264 can be a hole or electron transportation layer 264. In some embodiments, the second type carrier transportation layer 264 and the first type carrier transportation layer 262 is respectively configured for opposite types of charges. In some embodiments, a second type carrier injection layer (not shown in the figures) is further disposed over the second type carrier transportation layer 264. In some embodiments, the EM layer 263 is configured to emit a first color.

In some embodiments, the first type carrier injection layer 261, the first type carrier transportation layer 262, the organic EM layer 263, and the second type carrier transportation layer 264 may be formed by various deposition techniques such as Atomic Layer Deposition (ALD), Chemical Vapor Deposition (CVD), Physical Vapor Deposition (PVD), sputtering, plating, Laser Induced Thermal Imaging (LITI), inkjet printing, shadow mask, or wet coating.

In some embodiments, the first type carrier injection layer 261, the first type carrier transportation layer 262, the EM layer 263, and the second type carrier transportation layer 264 are configured to be divided into segments. In other words, the first type carrier injection layer 261, the first type carrier transportation layer 262, the EM layer 263, and the second type carrier transportation layer 264 are not continuously lining along the exposed top surface 250A and the first electrodes 215.

The light emitting unit 21 has a discontinuous and segmented first type carrier injection layer 261 disposed on the first electrode 215. The light emitting unit 21 has a discontinuous and segmented first type carrier transportation layer 262 disposed on the first type carrier injection layer 261. The light emitting unit 21 has a discontinuous and segmented EM layer 263 disposed on the first type carrier transportation layer 262. The light emitting unit 21 has a discontinuous and segmented second type carrier transportation layer 264 disposed on the EM layer 263.

In some embodiments, the first type carrier injection layer 261, the first type carrier transportation layer 262, the EM layer 263, and/or the second type carrier transportation layer 264 are in contact with the substrate 250 on gaps between first electrodes 215.

In some embodiments, the recess 313 formed as illustrated in FIGS. 6 and 7 has a width W wide enough to allow the first type carrier injection layer 261, the first type carrier transportation layer 262, the EM layer 263, and/or the second type carrier transportation layer 264 contact the substrate 250 on gaps between first electrodes 215.

In some embodiments, the first type carrier injection layer 261 at least partially covers the top surface 215B, and a meeting point of the top surface 215B and the sidewall 215C. In some embodiments, the first type carrier injection layer 261 and on the top surface 215B further extends to cover at least a portion of the sidewall 215C. In some embodiments, the first type carrier injection layer 261 is in contact with the top surface 215B and the sidewall 215C.

In some embodiments, the first type carrier injection layer 261, the first type carrier transportation layer 262, the EM layer 263, and/or the second type carrier transportation layer 264 are disposed following the surface topography of the first electrode 215. In some embodiments, the first type carrier injection layer 261, the first type carrier transportation layer 262, the EM layer 263, and/or the second type carrier transportation layer 264 are disposed conformally on the first electrode 215.

In some embodiments, the first type carrier transportation layer 262 is disposed following the surface topography of the first type carrier injection layer 261. In some embodiments, the EM layer 263 is disposed following the surface topography of the first type carrier transportation layer 262. In some embodiments, the second type carrier transportation layer 264 is disposed following the surface topography of the EM layer 263.

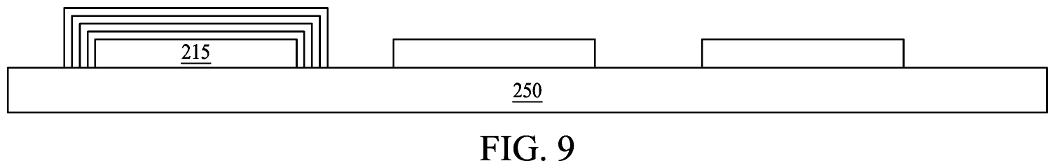

In FIG. 9, after the first type carrier injection layer 261, the first type carrier transportation layer 262, the EM layer 263, and the second type carrier transportation layer 264 of the first light emitting unit 21 is formed as illustrated in FIG. 8; the buffer layer 301 and the photosensitive layer 302 are completely removed. In some embodiments, the buffer layer 301 is configured to promote the removal operation of the photosensitive layer 302 by providing a less adhesive force between the substrate 250 and the photosensitive layer 302.

After the buffer layer 301 and the photosensitive layer 302 are completely removed, similar operations like FIGS. 4 to 8 can be repeated to form a different colored light emitting unit.

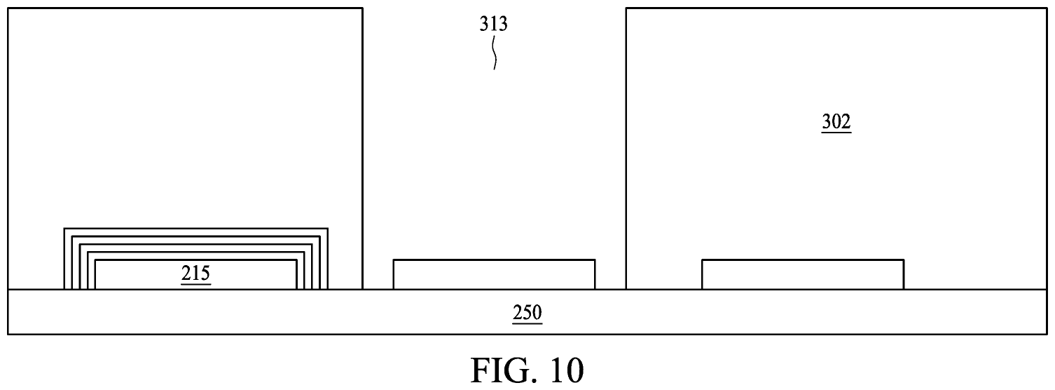

For some embodiments, the buffer layer 301 may be omitted, as illustrated in FIG. 10. For example, the operation of disposing a buffer layer may be skipped.

In FIG. 10, the photosensitive layer 302 is disposed and partially is removed to have a recess 313 to expose one of the first electrodes 215. After the photosensitive layer 302 is disposed, similar operations like FIGS. 8 to 9 can be repeated to form a different colored light emitting unit. For examples, operation of disposing multiple layers, and operation of removing the photosensitive layer can be repeated.

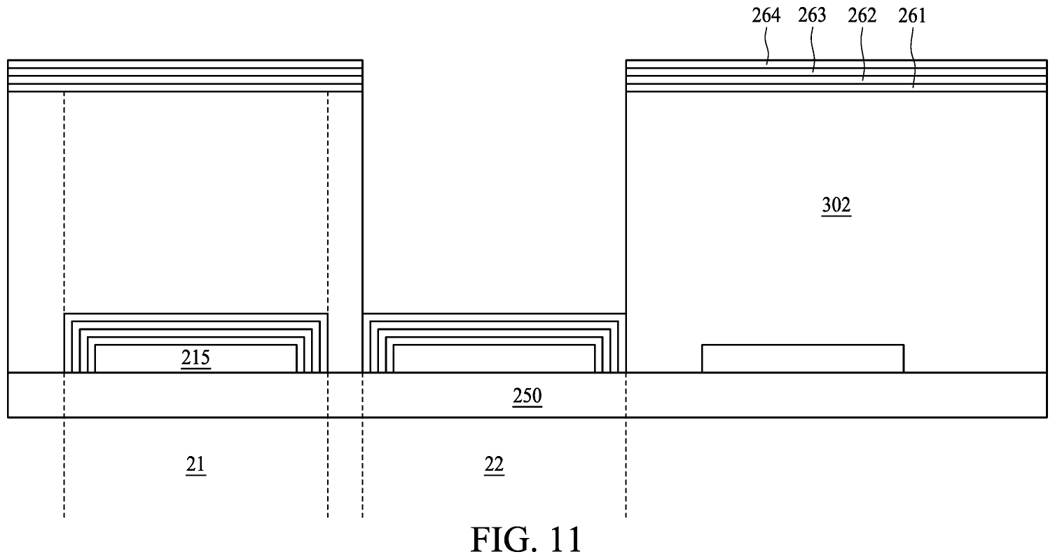

FIG. 11 illustrates the first type carrier injection layer 261, the first type carrier transportation layer 262, the organic EM layer 263, and the second type carrier transportation layer 264 are sequentially disposed over the exposed first electrode 215 of the second light emitting unit 22 and the exposed top surface 250A.

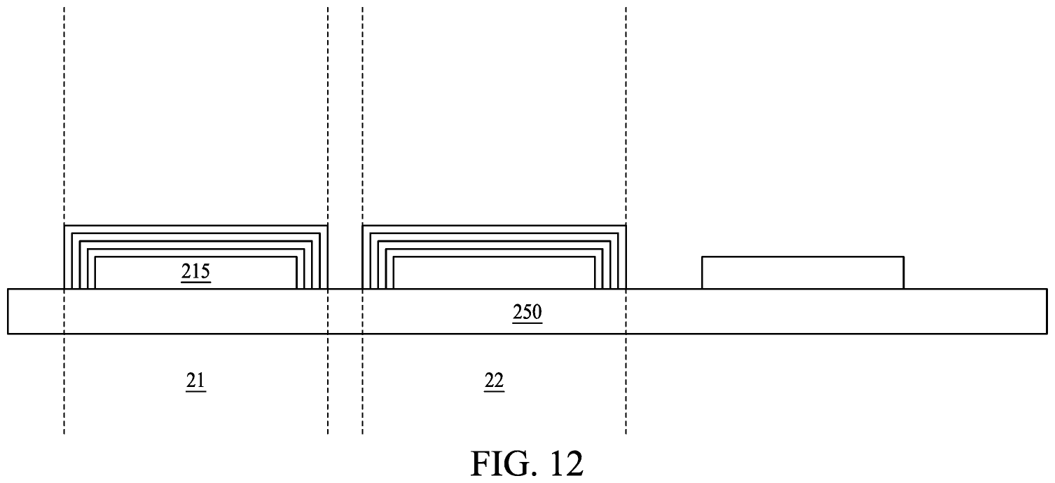

The second light emitting unit 22 emitting the second color, which is different from the first color of the first light emitting unit 21. In FIG. 12, after the first type carrier injection layer 261, the first type carrier transportation layer 262, the EM layer 263, and the second type carrier transportation layer 264 of the second light emitting unit 22 is formed; the photosensitive layer 302 are completely removed.

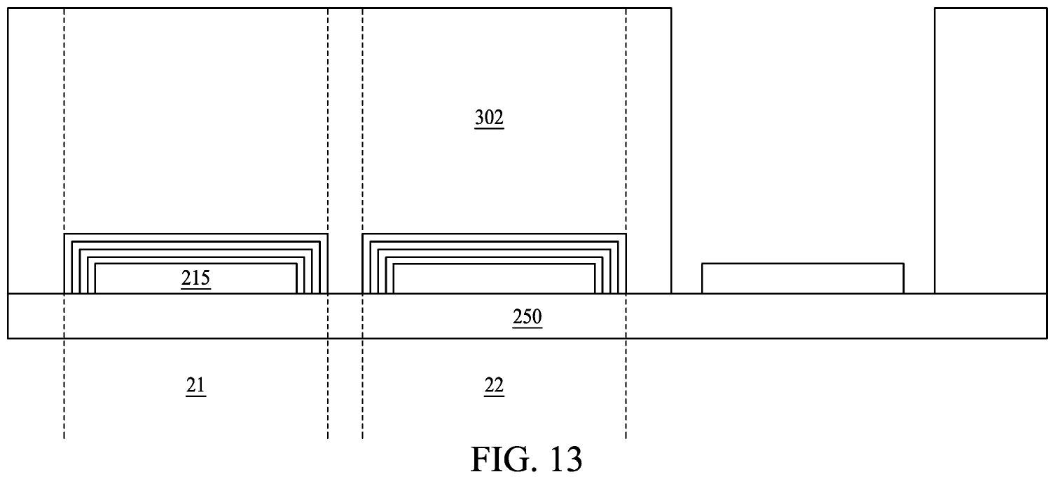

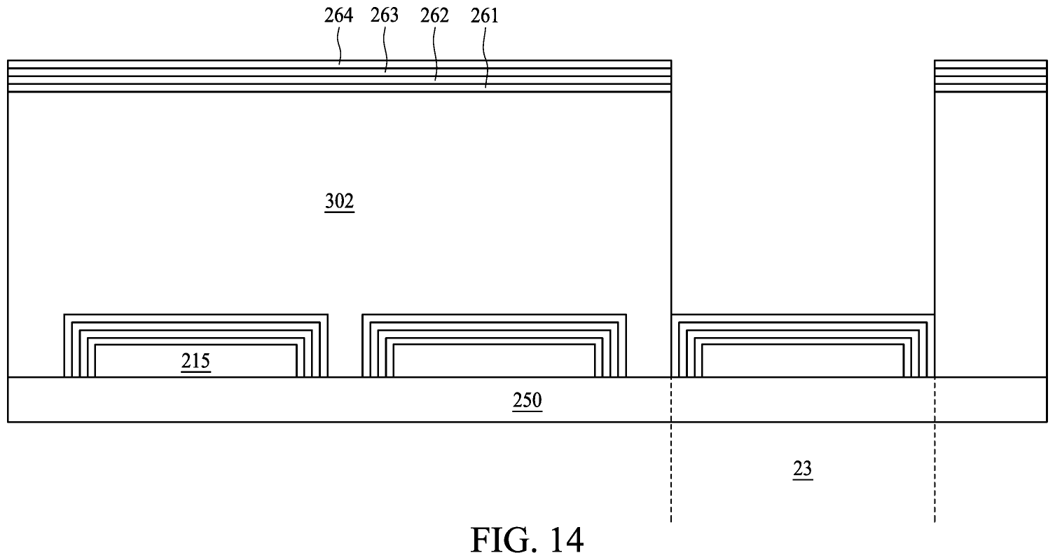

In FIG. 13, to form the third light emitting unit 23, another photosensitive layer 302 is disposed to cover the first light emitting unit 21 and the second light emitting unit 22. FIG. 14 further illustrates the third light emitting unit 23 emitting the third color, which is different from the first color and the second color.

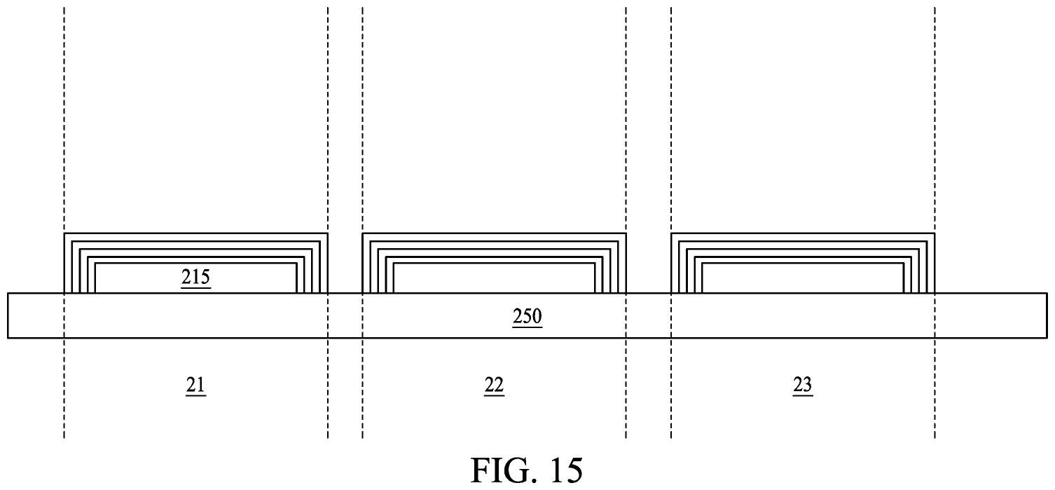

In FIG. 15, after the first type carrier injection layer 261, the first type carrier transportation layer 262, the EM layer 263, and the second type carrier transportation layer 264 of the third light emitting unit 23 is formed; the photosensitive layer 302 is completely removed.

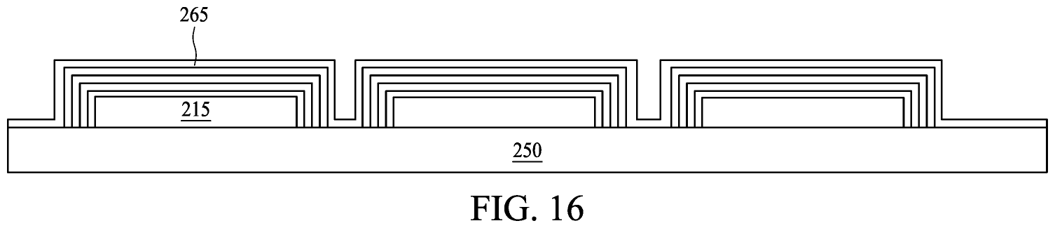

In FIG. 16, a second electrode 265 may be disposed over the second type carrier transportation layers 264 of the light emitting units 21, 22, and 23. In some embodiments, the second electrode 265 may be disposed after the last second type carrier transportation layer 264 of one of the light emitting units is formed. In some embodiments, the second electrode 265 covers the exposed top surface 250A of the substrate 250. In some embodiments, the second electrode 265 is disposed along sidewalk of the second type carrier transportation layers 264.

In some embodiments, the second electrode 265 can be metallic material such as Ag, Mg, etc. In some embodiments, the second electrode 265 includes ITO (indium tin oxide), or IZO (indium zinc oxide). In some embodiments, the second electrode 265 for the light emitting units is continuous.

In some embodiments, the first type carrier injection layer 261, the first type carrier transportation layer 262, the EM layer 263, the second type carrier transportation layer 264 are discontinuous and segmented among the light emitting units. In some embodiments, the second electrode 265 is commonly shared among the light emitting units.

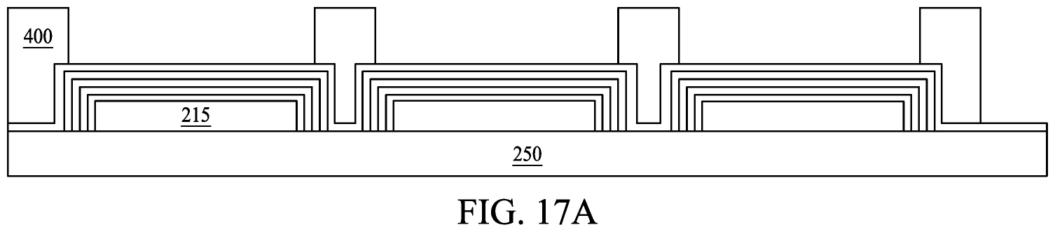

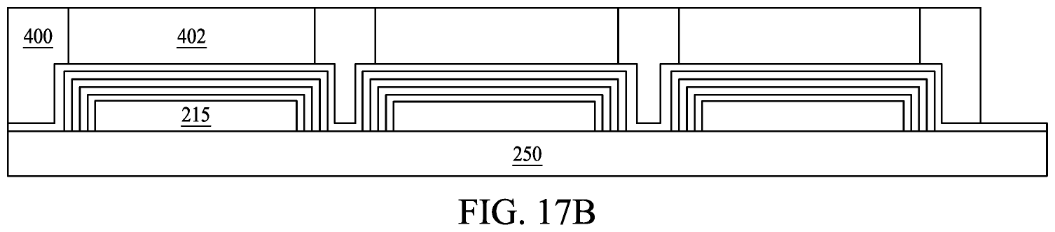

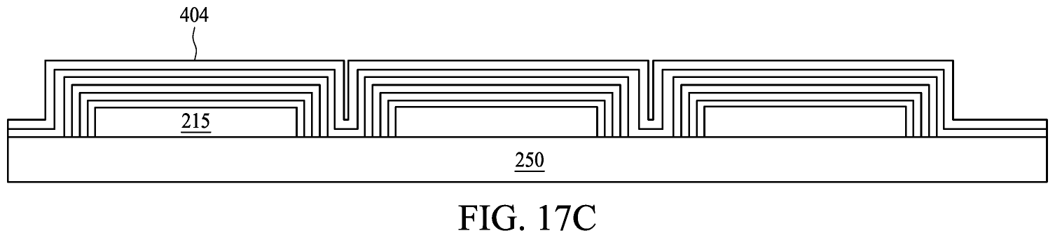

Referring to FIGS. 17A to 17C, FIGS. 17A to 17C illustrate the manufacturing operations after the second electrode 265 is disposed as illustrated in FIG. 16.

In FIG. 17A, a photosensitive layer 400 is disposed on the second electrode 265 and further patterned by a lithography process. In the cross sectional view, the remaining photosensitive layer forms several bumps. In some embodiments, each bump fills the gap between two adjacent light emitting units. The bumps are also called pixel defined layer (PDL). The bump can be formed in different types of shape. In some embodiments, the bump has a curved surface. In some embodiments, the shape of bump is trapezoid.

In some embodiments, after the bumps formed, a cleaning operation is performed to clean the exposed surfaces of the bumps. In one embodiment, during the cleaning operation, a DI (De-Ionized) water is heated to a temperature between 30° C. and 80° C. After the temperature of DI water is elevated to a predetermined temperature then is introduced to the exposed surfaces of the bumps.

In some embodiments, ultrasonic is used during the cleaning operation. The ultrasonic is introduced into the cleaning agent, such as water or IPA, etc. In some embodiments, carbon dioxide is introduced into the cleaning agent. After the cleaning operation, the cleaning agent is removed from the exposed surfaces via a heating operation. During the heating operation, the bumps may be heated to a temperature between about 80° C. and 110° C. In some cases, a compressed air is introduced to the exposed surfaces to help remove the residue of clean agent while heating.

After the heating operation, the exposed surfaces may be treated with an O₂, N₂, or Ar plasma. The plasma is used to roughen the exposed surfaces. In some embodiments, an ozone gas is used to adjust the surface condition of the exposed surfaces.

In FIG. 17B, a filling layer 402 is disposed to fill the gap between two adjacent bumps. In some embodiments, the filling layer 402 is transparent to the colors emitted by the light emitting units. In some embodiments, the filling layer 402 is substantially coplanar with the photosensitive layer 400. In some embodiments, the filling layer 402 and the photosensitive layer 400 are alternatively ordered.

In some embodiments, the filling layer 402 includes a different material from the photosensitive layer 400. In some embodiments, the filling layer 402 is a photosensitive layer as the photosensitive layer 400. In some embodiments, the filling layer 402 is a non-photosensitive layer. In some embodiments, the filling layer 402 is an encapsulating layer. In some embodiments, the encapsulating layer has the role to reduce the ingress of water and oxygen from environmental atmosphere.

In FIG. 17C, an encapsulating layer 404 is disposed on the second electrode 265. In some embodiments, the encapsulating layer 404 is disposed following the surface topography of the second electrode 265. In some embodiments, the encapsulating layer 404 is formed by depositing multiple component layers of different materials. In some embodiments, the encapsulating layer 404 comprises component layers of an organic material and of an inorganic material. In some embodiments, the encapsulating layer 404 comprises component layers of a polymer and of a ceramic material.

In some embodiments, the encapsulating layer 404 includes one or more materials of the group including: Zn, ZnSe, ZnS₁₋ₛSeₓ, ZnTe, CaS, SrS, BaS, SrS₁₋ₓSₓ, CdS, CdTe, MnTe, HgTe, Hg₁₋ₓCdₓTex, Cd₁₋ₓMnₓTe, AlN, GaN, InN, SiNₓ, Ta₃N₅, TiN, TiSiN, TaN, NbN, MoN, W₂N, Al₂O₃, TiO₂, ZrO₂, HfO₂, Ta₂O₅, Nb₂O₅, Y₂O₃, MgO, CeO₂, SiO₂, La₂O, SrTiO₃, BaTiO₃, BiₓTi_{y}, O_{z}, Indium Tin Oxide, Indium Oxide, SnO₂, NiO, C0₃O₄, MnOₓ, LaCoO₃, LaNiO₃, LaMnO₃, CaF₂, SrF₂, ZnF₂, Si, Ge, Cu, Mo, Ta, W, La₂S₃, PbS, In₂S₃, CuGaS₂, and SiC where x, y and z are positive integers.

Some embodiments of the present disclosure provide a light emitting device. The light emitting device includes a substrate, and an array of light emitting units over the substrate. Each of the light emitting units includes a first electrode. The first electrode includes a bottom surface on the substrate, a top surface opposite to the bottom surface, and a sidewall between the bottom surface and the top surface. Each of the light emitting units further includes a second electrode over the first electrode and facing the top surface. Each of the light emitting units further includes an organic layer between the first electrode and the second electrode. The organic layer at least partially covers the top surface and a meeting point of the top surface and the sidewall. The organic layer is discontinuous among the light emitting units.

Some embodiments of the present disclosure provide a method for manufacturing a light emitting device. The method includes providing a substrate, and forming a first electrode on the substrate. The method also includes forming a photosensitive layer over the substrate, and patterning the photosensitive layer to form a recess through the photosensitive layer to expose a top surface of the first electrode. The method also includes disposing an organic layer on the top surface, and completely removing the patterned photosensitive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present invention. Accordingly, the appended claims are intended to include within their scope such processes, machines, manufacture, compositions of matter, means, methods, or steps.

What is claimed is:

1. A light emitting device, comprising:
a substrate;
an array of light emitting units over the substrate, each of the light emitting units comprising:
a first electrode including a bottom surface on the substrate, a top surface opposite to the bottom surface, and a sidewall between the bottom surface and the top surface;
a second electrode over the first electrode and facing the top surface;
an organic layer between the first electrode and the second electrode, wherein the organic layer at least partially covers the top surface and a meeting point of the top surface and the sidewall;
wherein the organic layer is discontinuous among the light emitting units, the second electrode is in contact with the surface of the substrate between the light emitting units.

2. The light emitting device in claim 1, wherein the organic layer is a carrier transportation layer.

3. The light emitting device in claim 1, wherein the organic layer is a carrier injection layer.

4. The light emitting device in claim 1, wherein the organic layer is an organic emissive layer.

5. The light emitting device in claim 1, wherein the organic layer further extends to cover at least a portion of the sidewall.

6. The light emitting device in claim 1, wherein the organic layer is in contact with the substrate.

7. The light emitting device in claim 1, wherein the organic layer includes a carrier transportation layer disposed on the first electrode, a carrier injection layer disposed on the carrier transportation layer, and an organic emissive layer disposed on the carrier injection layer.

8. The light emitting device in claim 1, further comprises a photosensitive layer disposed on the second electrode.

9. The light emitting device in claim 8, wherein the photosensitive layer comprises several bumps, and each of the bumps fills a gap between two of the light emitting units.

10. The light emitting device in claim 9, further comprises a filling layer fills a gap between two of the bumps.

11. The light emitting device in claim 10, wherein the filling layer and the bumps are alternatively ordered.

12. The light emitting device in claim 1, further comprises an encapsulating layer disposed on the second electrode.

13. A method for manufacturing a light emitting device, comprising:
providing a substrate;
forming a plurality of first electrodes on the substrate;
forming a photosensitive layer over the substrate;
patterning the photosensitive layer to form a recess through the photosensitive layer to expose a top surface of the first electrode and to partially expose the top surface of the substrate, wherein the substrate is partially exposed through the first electrode;
disposing an organic layer on the top surface of the first electrode and the top surface of the photosensitive layer simultaneously; and
completely removing the patterned photosensitive layer and the organic layer disposing on the top surface of the photosensitive layer.

14. The method for manufacturing a light emitting device in claim 13, wherein the first electrode including a bottom surface opposite to the top surface, and a sidewall between the bottom surface and the top surface; and
wherein the organic layer at least partially covers the top surface and a meeting point of the top surface and the sidewall.

15. The method for manufacturing a light emitting device in claim 13, further comprising:
forming a buffer layer between the photosensitive layer and the substrate.

16. The method for manufacturing a light emitting device in claim 15, wherein the buffer layer is organic and includes fluorine.

17. The method for manufacturing a light emitting device in claim 13, further comprising:
forming a second electrode on the organic layer, wherein the second electrode is in contact with the substrate.

18. The method for manufacturing a light emitting device in claim 15, further comprising:
forming a photosensitive layer on the second electrode.

19. The method for manufacturing a light emitting device in claim 13, further comprising:
forming an encapsulating layer over the substrate.

20. A light emitting device, comprising:
a substrate;
an array of light emitting units over the substrate, each of the light emitting units comprising:
a first electrode including a bottom surface on the substrate, a top surface opposite to the bottom surface, and a sidewall between the bottom surface and the top surface;
a second electrode over the first electrode and facing the top surface of the first electrode;
an first organic layer between the first electrode and the second electrode, wherein the first organic layer at least partially covers the top surface of the first electrode and a meeting point of the top surface and the sidewall of the first electrode;
a second organic layer between the first organic layer and the second electrode, wherein the second organic layer covers the first organic layer;
wherein the first organic layer and the second organic layer are divided by a region between two adjacent light emitting units in the array of light emitting units and coplanarly in contact with a surface of the substrate which is exposed from the two adjacent light emitting units in the array of light emitting units.
